(19) United States
(12) Patent Application Publication
(10) Pub. No.: US 2011/0106469 A1
(43) Pub. Date: May 5, 2011

(54) CIRCUIT AND METHOD FOR DETECTING SHORT AND DISCONNECTION OF RESOLVER FOR HYBRID ELECTRIC VEHICLE

(75) Inventors: Chul Woo Kim, Hwaseong (KR); Bum Sik Kim, Gwangmyeong (KR); Tae Hwan Chung, Hwaseong (KR); Young Kook Lee, Seoul (KR); Jin Hwan Jung, Suwon (KR); Sang Hyeon Moon, Anyang (KR); Sung Kyu Kim, Bucheon (KR); Jae Won Lee, Hwaseong (KR)

(73) Assignee: HYUNDAI MOTOR COMPANY, Seoul (KR)

(21) Appl. No.: 12/829,323

(22) Filed: Jul. 1, 2010

(30) Foreign Application Priority Data
Nov. 4, 2009 (KR) 10-2009-0105771

(51) Int. Cl. G01R 31/00

(52) U.S. Cl. 702/58; 180/65.275

(57) ABSTRACT

The present invention relates to a circuit and method for detecting a short and a disconnection of a resolver for a Hybrid Electric Vehicle (HEV), which can accurately analyze and detect the fault code of the resolver which detects the speed of a drive motor for an HEV and the angle of a rotator for an HEV.

For this, the circuit of the present invention is configured such that resistors for detection of a short/disconnection are connected between output signal terminals of a resolver which are connected to input terminals of an RDC connected to a CPU, and the CPU measures certain voltages, obtained according to voltage division by the resistors for detection of a short/disconnection and pull-up resistors connected between a power source and the output signal terminals, with reference to differential signals which are output signals provided to the RDC through the output signal terminals.

### CROSS-REFERENCE TO RELATED APPLICATION

This application claims under 35 U.S.C. §119(a) the benefit of Korean Patent Application No. 10-2009-0105771 filed Nov. 4, 2009, the entire contents of which are incorporated herein by reference.

### BACKGROUND

(a) Technical Field

The present disclosure relates generally to a circuit and method for detecting a short and a disconnection of a resolver for a hybrid electric vehicle (HEV), which can accurately analyze and detect the fault code of the resolver which detects the speed of a drive motor for an HEV and the angle of a rotator for an HEV.

(b) Background Art

A hybrid electric vehicle (HEV) using an engine and a motor is a futuristic vehicle configured such that it starts to drive by using a drive motor in initial start-up, and such that, when the vehicle reaches a predetermined speed, it drives by starting the engine and by simultaneously utilizing the power of the engine and the power of the drive motor, thus realizing the reduction of waste gas and the improvement of fuel economy. In an HEV, a high-voltage battery for driving the drive motor is chargeably or dischargeably connected to the drive motor via an inverter.

In particular, a resolver for detecting the speed of the drive motor and the angle of a rotator is adopted in the HEV. The sensing and fault detection by the resolver is one of the very important factors in the control of the motor.

Currently, a method of determining a fault occurring in a resolver is performed as follows. That is, as shown in FIG. 4, when a fault occurs in the input signals (excitation signals EXT+ and EXT−) or output signals (base signals for speed sensing S1-S3 and S2-S4) of the resolver, a fault signal FAULT is generated by a Resolver-to-Digital Converter (RDC). Subsequently, as the fault signal, a digital signal, is input to a Central Processing Unit (CPU), it can be determined that the resolver is faulty.

However, it is impossible to accurately determine disconnections/shorts occurring in the resolver or the resolver's own malfunctioning on a per-fault code basis by using only the fault signal generated by the RDC, and thus a user (repairman) can be aware of only the fact that a fault is present in the resolver.

Consequently, when the fault signal from the resolver is input to the CPU via the RDC, a fault code corresponding to the cause of the fault cannot be known, and thus there is a considerable problem when analyzing the fault of the resolver.

That is, when a fault occurs in the resolver, measurement equipment (for example, oscilloscope) is connected to an inverter or a drive motor for an HEV and configured to detect the cause of the fault in the resolver in order to detect the accurate cause of the fault. Therefore, a problem arises in that it takes a long time to detect the cause of the fault.

Japanese Patent Application Publication No. 2004-147463 discloses a motor driving device. The motor driving device includes rotary position sensors for detecting the rotary positions of motors, and a fault detection means for detecting the rotation speeds N1 and N2 of respective motors, comparing N1 with N2, and determining that at least one rotary position sensor is faulty when the rotation speeds N1 and N2 differ by a predetermined value or more.

Further, Japanese Patent Application Publication No. 11-337373 discloses a diagnosis scheme. In the diagnosis scheme, a VR resolver, an R/D Converter (RDC), and a rotary motion sensor are provided, two or more pairs of an excitation coil and a detection coil are installed in one stator of the resolver, and R/D converters for respectively converting detected signals output from the detection coils of the respective pairs are installed, thus diagnosing the faults of the rotary motion sensor by checking the reasonability of the output signals of the R/D converters. However, similarly, this scheme is disadvantageous in that it is impossible to accurately determine the cause of the fault in the resolver in regard to whether the cause of the fault is a disconnection or a short.

The above information disclosed in this Background section is only for enhancement of understanding of the background of the invention and therefore it may contain information that does not form the prior art that is already known in this country to a person of ordinary skill in the art.

### SUMMARY OF THE DISCLOSURE

In one aspect, the present invention provides a circuit for detecting short and a disconnection of a resolver for a hybrid electric vehicle (HEV). The circuit includes a resolver, a resolver-to-digital converter (RDC), a central processing unit (CPU), a resistor (Ro), and a pull-up resistor (Rp).

The resolver includes output signal terminals. Via the output signal terminals differential signals (S1-S3 and S2-S4) are outputted. The RDC receives the differential signals from the resolver and is configured to issue a fault signal depending on the received differential signals. The CPU is interconnected to the RDC for receiving the fault signal therefrom. The Ro functions to detect short and disconnection and is installed between the output signal terminals. The Rp is connected between a power source and the output signal terminals. The CPU is configured to measure a voltage of each differential signal that is subjected to a voltage division between the Ro and the Rp, and determine short and disconnection of the resolver based on the measured voltage.

In another aspect, the present invention provides a method of detecting short and disconnection of a resolver for a hybrid electric vehicle (HEV). The method comprises: providing resistors (Ro) for detecting short and disconnection between Output signal terminals of a resolver; providing pull-up resistors (Rp) connected between a power source and the output signal terminals; measuring a voltage of each differential signal (S1-S3 and S2-S4), the voltage being subjected to a voltage division between the resistors (Ro) and the pull-up resistors (Rp); and determining short or disconnection of the resolver based on the measured voltage.

In a preferred embodiment, as a result of measurement of the certain voltages generated by the output signals (S1-S3 and S2-S4) of the resolver, when a value corresponding to [Ro/(Ro+Rp)*power] is maintained for a predetermined period of time, the resolver is determined to be disconnected.

In another preferred embodiment, as a result of measurement of the certain voltages generated by the output signals (S1-S3 and S2-S4) of the resolver, when a value corresponding to 0V is maintained for a predetermined period of time, the resolver is determined to be shorted.

According to the present invention, resistors for the detection of a short/disconnection are added to the fault logic of a resolver which detects the speed of a drive motor for an HEV and the angle of a rotator, so that the present invention can accurately analyze and determine whether a fault in the resolver is a disconnection or a short, and can transmit accurate details related to the diagnosis of a fault to a user. Thus, the present invention is advantageous in that it can be usefully used for debugging in the development stage of detection circuits, and in that, if After/Service (A/S) is required even after circuit production, the situation of faults in the resolver can be accurately determined, thus allowing faults to be promptly and accurately coped with.

### BRIEF DESCRIPTION OF THE DRAWINGS

The above and other features of the present invention will now be described in detail with reference to certain exemplary embodiments thereof illustrated the accompanying drawings which are given hereinbelow by way of illustration only, and thus are not imitative of the present invention, and wherein:

FIG. 1 is a circuit diagram showing a circuit for performing a method of detecting a short and a disconnection of a resolver for an HEV according to an embodiment of the present invention;

FIG. 2 is a flowchart showing the method of detecting a short and a disconnection of a resolver for an HEV according to an embodiment of the present invention;

FIG. 3 is a schematic diagram showing the structure of an RDC chip for receiving output signals from the resolver for an HEV; and

FIG. 4 is a schematic diagram showing the construction of a signal transmission scheme of a resolver for detecting the speed of a motor and the angle of a rotator.

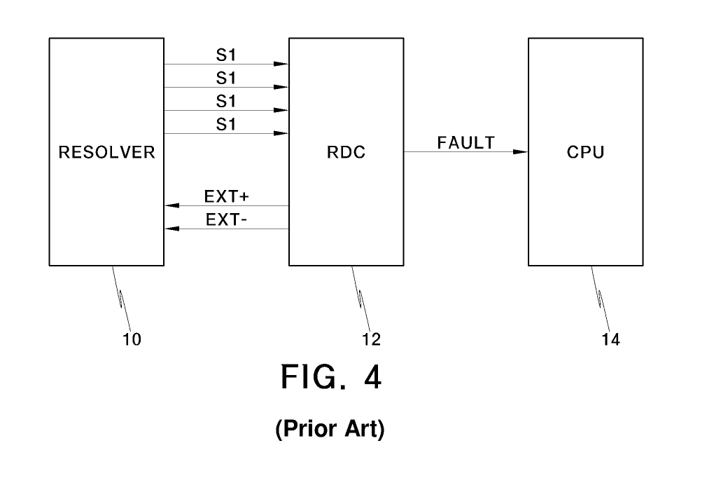

It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter reference will now be made in detail to various embodiments of the present invention, examples of which are illustrated in the accompanying drawings and described below. While the invention will be described in conjunction with exemplary embodiments, it will be understood that present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

Hereinafter, embodiments of the present invention will be described in detail with the attached drawings.

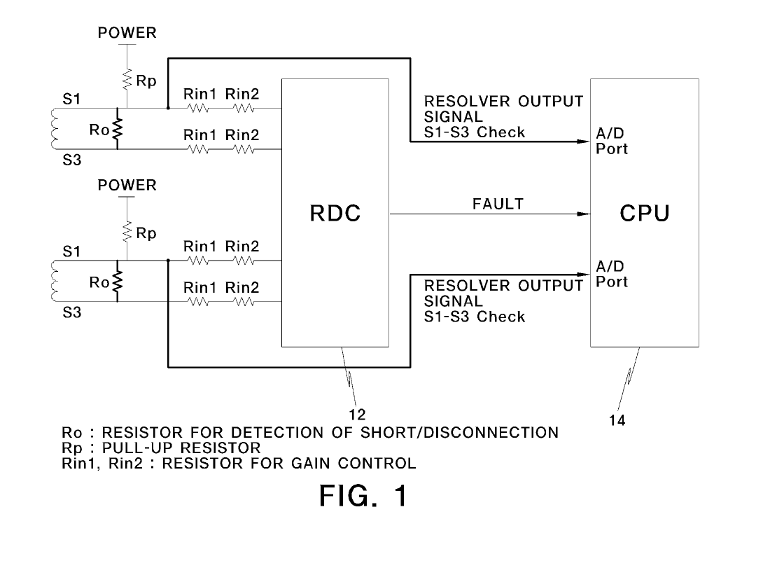

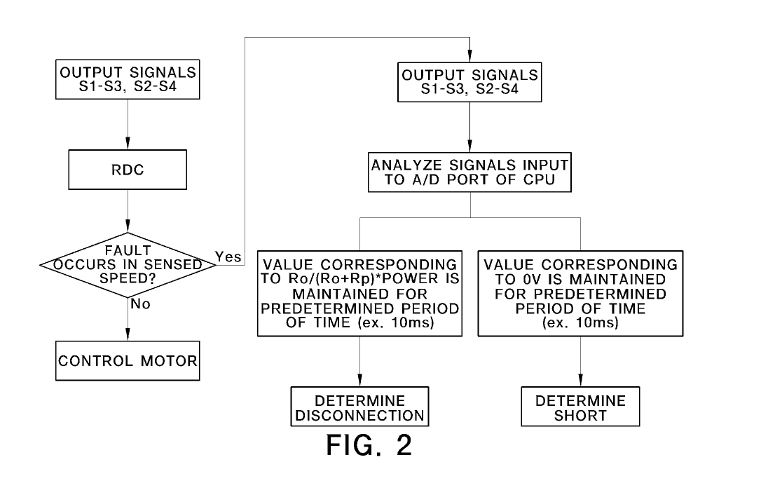

FIG. 1 is a circuit diagram showing a circuit for detecting a short and a disconnection of a resolver for a Hybrid Electric Vehicle (HEV) according to the present invention, and FIG. 2 is a flowchart showing a method of detecting a short and a disconnection of a resolver for an HEV according to the present invention.

For ease of understanding of the present invention, the construction and function of a resolver will be described in brief.

In order to perform vector control of a synchronous motor or an induction motor used in a hybrid electric vehicle (HEV) or a pure electric vehicle (EV), a coordinate system must be set in synchronization with the flux position of the motor. For this operation, there is a need to read the absolute location of the rotator of the motor. Thus, a resolver is used to detect the absolute location of the rotator (rotation angle).

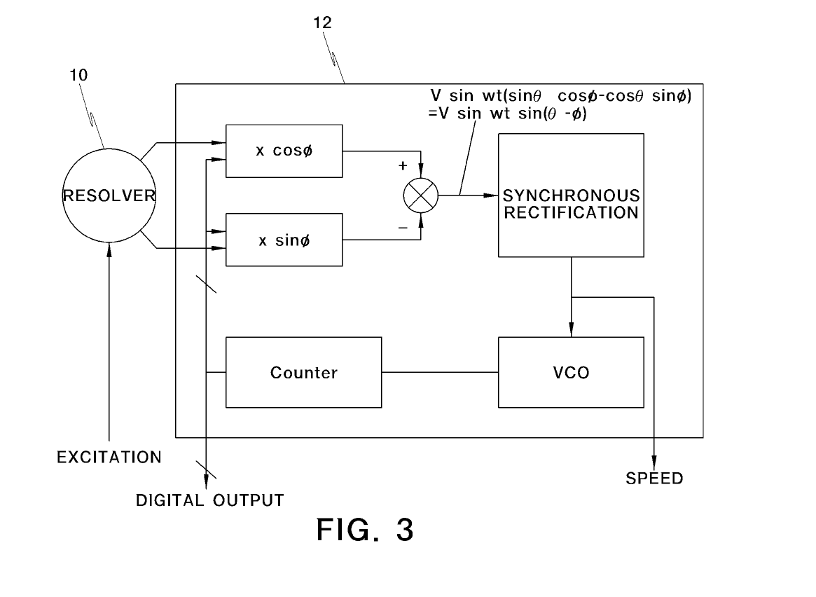

In this way, individual phases of the rotator are accurately sensed by the resolver, and are transferred from a Resolver-to-Digital Converter (RDC) (refer to FIG. 3) to a Central Processing Unit (CPU), wherein the RDC includes a synchronous rectification unit for rectifying the sensed values, a Voltage-Controlled Oscillator (VCO) for outputting a desired oscillation frequency using a synchronously rectified voltage, etc. Accordingly, the circuit of FIG. 1 can accurately perform the speed control and torque control of the motor required for the HEV and EV. Differential signals S1-S3 and S2-S4, which are output signals of the resolver that perform the above functions, have a frequency of 10 kHz and have an Alternating Current (AC) voltage of 1V to 4V in normal conditions. However, when the differential signals fall out of the ranges, that is, when faults occur in the input signals (excitation signals EXT+ and EXT−) or the output signals (base signals for speed sensing, S1-S3 and S2-S4) of the resolver, a fault signal FAULT is generated by the RDC. As the fault signal is input to the CPU, the CPU determines that the resolver is faulty.

The present invention principally aims to promptly and accurately cope with the occurrence of a fault in the development and production stages by accurately determining whether a fault in the resolver is a short or a disconnection.

For this principal aim, as shown in the circuit diagram of FIG. 1, the respective output signal terminals 16 of a resolver 10 are connected to the input terminals of an RDC 12, the output terminals of which are connected to a CPU 14. Resistors Ro for the detection of a short/disconnection are connected between the output signal terminals 16.

For reference, reference numerals Rin1 and Rin2, not described, denote resistors for gain control.

Therefore, the differential signals S1-S3 and S2-S4, which are output signals provided to the RDC 12 via the output signal terminals 16, are monitored by the CPU, so that certain voltages obtained according to the voltage division by the resistors Ro for the detection of a short/disconnection and the pull-up resistors Rp connected between a power source and the output signal terminals 16 can be measured by the CPU 14.

That is, the CPU 14 measures certain voltages, obtained according to the voltage division by the resistors Ro for the detection of a short/disconnection and the pull-up resistors Rp connected to the power source, with reference to the differential signals S1-S3 and S2-S4 which are output signals provided through the output signal terminals 16, and thus accurately determines the disconnection or short of the resolver 10.

A method of determining the disconnection or the short of the resolver 10 may be implemented in such a way that, as a result of the measurement of the certain voltages generated by the output signals S1-S3 and S2-S4 of the resolver, when a value corresponding to [Ro/(Ro+Rp)*power] is maintained for a predetermined period of time or longer (10 ms or longer), the resolver is determined to be disconnected, and that, when a value corresponding to 0V is maintained for a predetermined period of time or longer (10 ms or longer), the resolver is determined to be shorted.

As described above, according to the present invention, resistors for the detection of a short/disconnection are added to the fault logic of a resolver which detects the speed of a drive motor and the angle of a rotator, so that the present invention can accurately determine whether a fault in the resolver is a disconnection or a short, and can transmit accurate details related to the diagnosis of the fault to a user. Thus, the present invention provides advantages in that it can be usefully utilized for debugging in the development stage of detection circuits, and in that, if After/Service (A/S) is required even after circuit production, the situation of faults in the resolver can be accurately determined, thus allowing faults to be promptly and accurately coped with.

The invention has been described in detail with reference to preferred embodiments thereof. However, it will be appreciated by those skilled in the art that changes may be made in these embodiments without departing from the principles and spirit of the invention, the scope of which is defined in the appended claims and their equivalents.

What is claimed is:

1. A circuit for detecting short and a disconnection of a resolver for a hybrid electric vehicle (HEV), comprising:
a resolver having output signal terminals, via which differential signals (S1-S3 and S2-S4) are outputted;
a resolver-to-digital converter (RDC) receiving the differential signals from the resolver, the RDC configured to issue a fault signal depending on the received differential signals;
a central processing unit (CPU), the CPU being interconnected to the RDC for receiving the fault signal therefrom;
a resistor (Ro) for detecting short and disconnection, the resistor installed between the output signal terminals; and
a pull-up resistor (Rp) connected between a power source and the output signal terminals,
wherein the CPU is configured to measure a voltage of each differential signal that is subjected to a voltage division between the resistor (Ro) and the pull-up resistor (Rp), and determine short and disconnection of the resolver based on the measured voltage.

2. A method of detecting short and disconnection of a resolver for a hybrid electric vehicle (HEV), comprising steps of:
providing resistors (Ro) for detecting short and disconnection between Output signal terminals of a resolver;
providing pull-up resistors (Rp) connected between a power source and the output signal terminals;
measuring a voltage of each differential signal (S1-S3 and S2-S4), the voltage being subjected to a voltage division between the resistors (Ro) and the pull-up resistors (Rp); and
determining short or disconnection of the resolver based on the measured voltage.

3. The method of claim 2, wherein, as a result of measurement of the certain voltages generated by the output signals (S1-S3 and S2-S4) of the resolver, when a value corresponding to [Ro/(Ro+Rp)*power] is maintained for a predetermined period of time, the resolver is determined to be disconnected.

4. The method of claim 2, wherein, as a result of measurement of the certain voltages generated by the output signals (S1-S3 and S2-S4) of the resolver, when a value corresponding to 0V is maintained for a predetermined period of time, the resolver is determined to be shorted.
